(19) United States
(12) Patent Application Publication
(10) Pub. No.: US 2008/0191333 A1
(43) Pub. Date: Aug. 14, 2008

(54) Image sensor package with die receiving opening and method of the same

(75) Inventors: Wen-Kun Yang, Hsin-Chu City (TW); Diann-Fang Lin, Hukou Township (TW); Jui-Hsien Chang, Jhudong Township (TW); Tung-chuan Wang, Yangmei Town (TW); Hsien-Wen Hsu, Lujhou City (TW)

Correspondence Address: BACON & THOMAS, PLLC, 625 SLATERS LANE, FOURTH FLOOR, ALEXANDRIA, VA, 22314, US

(73) Assignee: Advanced Chip Engineering Technology Inc., Hukou Township (TW)

(21) Appl. No.: 11/703,663

(22) Filed: Feb. 8, 2007

(51) Int. Cl. H01L 23/02; H01L 21/00

(52) U.S. Cl. 257/680; 438/116; 257/E23.18; 257/E21.001

(57) ABSTRACT

The present invention provides a structure of package comprising a substrate with a die through hole and a contact through holes structure formed there through, wherein a terminal pad is formed under the contact through hole structure and a contact pad is formed on a upper surface of the substrate. A die having a micro lens area is disposed within the die through hole by adhesion. A wire bonding is formed on the die and the substrate, wherein the wire bonding is coupled to the die and the contact pad. A protective layer is formed to cover the wire bonding. A transparent cover is disposed on the die within the die through hole by adhesion to expose the micro lens area. Conductive bumps are coupled to the terminal pads.

### FIELD OF THE INVENTION

This invention relates to a structure of Panel level package (PLP), and more particularly to a substrate with die receiving opening to receive an Image Sensor die for PLP.

### DESCRIPTION OF THE PRIOR ART

In the field of semiconductor devices, the device density is increased and the device dimension is reduced, continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As a semiconductor become more complicated, the traditional package technique, for example lead frame package, flex package, rigid package technique, can't meet the demand of producing smaller chip with high density elements on the chip.

Furthermore, because conventional package technologies have to divide a dice on a wafer into respective dies and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dice). Generally, after completion of all assembling processes or packaging processes, individual semiconductor packages are separated from a wafer having a plurality of semiconductor dies. The wafer level package has extremely small dimensions combined with extremely good electrical properties.

WLP technique is an advanced packaging technology, by which the die are manufactured and tested on the wafer, and then singulated by dicing for assembly in a surface-mount line. Because the wafer level package technique utilizes the whole wafer as one object, not utilizing a single chip or die, therefore, before performing a scribing process, packaging and testing has been accomplished; furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices.

Though the advantages of WLP technique mentioned above, some issues still exist influencing the acceptance of WLP technique. For example, although utilizing WLP technique can reduce the CTE mismatch between IC and the interconnecting substrate, as the size of the device minimizes, the CTE difference between the materials of a structure of WLP becomes another critical factor to mechanical instability of the structure. Furthermore, in this wafer-level chip-scale package, a plurality of bond pads formed on the semiconductor die is redistributed through conventional redistribution processes involving a redistribution layer into a plurality of metal pads in an area array type. Solder balls are directly fused on the metal pads, which are formed in the area array type by means of the redistribution process. Typically, all of the stacked redistribution layers are formed over the built-up layer over the die. Therefore, the thickness of the package is increased. This may conflict with the demand of reducing the size of a chip.

Therefore, the present invention provides a FO-WLP structure without stacked built-up layer and RDL to reduce the package thickness to overcome the aforementioned problem and also provide the better board level reliability test of temperature cycling.

### SUMMARY OF THE INVENTION

The present invention provides a structure of package comprising a substrate with a die through hole and a contact through holes structure formed there through, wherein terminal pads are formed under the contact through holes structure and contact pads are formed on a upper surface of the substrate. A die having a micro lens area is disposed within the die through hole by adhesion. A wire bonding is formed on the die and the substrate, wherein the wire bonding is coupled to bonding pads of the die and the contact pads of the substrate. A protective layer is formed to cover the wire bonding and fill into the gap between die edge and sidewall of die through hole to adhesive the die and substrate except the transparent cover area. A transparent cover is disposed on the die within the die through hole by adhesion to create an air gap between the transparent cover and the micro lens area. Conductive bumps are coupled to the terminal pads.

It should be noted that the present invention provide a method for forming semiconductor device, such as CMOS Image Sensor (CIS), package. Firstly, the process includes providing a substrate with a die through hole and a contact through holes structure formed there through on a tool, wherein the terminal pads are formed under said contact through holes structure and a contact pads are formed on an upper surface of said substrate. Next, an adhesive material is attached on image sensor chips back side (optional process). Subsequently, a pick and place fine alignment system is used to re-distribute known good dice image sensor chips on the tool with desired pitch. A wire bonding is formed to couple between the chip and contact pad of the substrate. Next, a protective layer is formed to cover the wire bonding and fill into the gap between the die edge and the sidewall of the die through hole, and vacuum curing then separating the tool. Finally, semiconductor device package is singulated into individual units.

The image sensor chips has been coated the protection layer (film) on the micro lens area; the protection layer (film) with the properties of water repellent and oil repellent that can away the particles contamination on the micro lens area; the thickness of protection layer (film) preferably around 0.1 um to 0.3 um and the reflection index close to air reflection index 1. The process can be executed by SOG (spin on glass) skill and it can be processed in silicon wafer form. The materials of protection layer can be SiO₂, Al₂O₃ or Fluoro-polymer etc.

The material of the substrate includes organic epoxy type FR4, FR5, BT, PCB (print circuit board), alloy or metal. The alloy includes Alloy42 (42% Ni-58% Fe) or Kovar (29% Ni-17% Co-54% Fe). Alternatively, the substrate could be glass, ceramic or silicon.

### BRIEF DESCRIPTION OF THE DRAWINGS

FIG. 1 illustrates a cross-sectional view of CIS-CSP (CMOS Image Sensor-Chip Size Package) in accordance with one embodiment of the present invention.

FIG. 2 illustrates a cross-sectional view of CIS-CSP (CMOS Image Sensor-Chip Size Package) in accordance with one embodiment of the present invention.

FIGS. 3a˜3d illustrate process steps for making CIS chips with protection transparent cover for the panel wafer form (cross section).

FIGS. 4a˜4e illustrate process steps for making CIS chips with protection transparent cover for the panel wafer form (cross section) according to another embodiment of the present invention.

FIGS. 5a˜5f illustrate process steps for making panel level CIS chip scale package with protection transparent cover for the panel form (cross section).

FIG. 6 illustrates a cross section view of CIS module in accordance with one embodiment of the present invention.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying Claims.

The present invention discloses a structure of Panel Level Package (PLP) utilizing a substrate having predetermined die through holes and contact (inter-connecting) through holes formed, and the contact metal pads on the upper side and the terminal metal pads on the lower side through the metal of through holes therein and a plurality of openings passing through the substrate. A wire bonding is connected between pads formed on an image sensor die and contact metal pads of the pre-formed substrate.

FIG. 1 illustrates a cross-sectional view of CIS-CSP (CMOS Image Sensor-Chip Size Package) in accordance with one embodiment of the present invention. As shown in the FIG. 1, the structure of PLP includes a substrate 2 having predetermined die through holes 10 and contact (inter-connecting) through holes 6 formed therein, wherein the die through hole is to receive a die 16. Preferably, the die 16 is an image sensor die. Pluralities of the contact through holes 6 are created through the substrate 2 from upper surface to lower surface of the substrate 2, wherein the contact (inter-connecting) through holes 6 is surrounded (peripheral type) by the substrate 2. A conductive material will be re-filled into the through holes 6 for electrical communication. Contact (terminal) pads 8 are located on the lower surface of the substrate 2 and connected to the contact through holes 6 with conductive material. Contact conductive, such as metal, pads 22 are located on the upper surface of the substrate 2 and also connected to the contact through holes 6 with conductive material. A terminal conductive pad 30 is configured on the lower surface of the substrate 2 to solder joining an external object. A wire bonding 24 is connected between pads 20 of the die 16 and contact metal pads 22 of the pre-formed substrate 2. A protective layer 26, for instance liquid compound, is formed over the wire bonding 24 for protection and filled into the gap between the die 16 edge and sidewall of die through hole 10 for adhesion. In one embodiment, material of the protective layer 26 comprises compound, liquid compound, silicone rubber, and the protection layer 26 may be formed by molding or gluing method (dispensing or printing).

The die 16 is disposed within the die through hole 10 and fixed by an adhesion tape (die attached—optional process) material 14 as the protection material for the backside of die. The dimension of the width (size) of the die through hole 10 could be larger than the width (size) of the die 16 around 100 um each side. As know, contact pads (bonding pads) 20 are formed on the die 16 by a metal plating method. In one embodiment, the protective layer (liquid compound) 26 will be re-filled into gap of the through holes 10 (between die edge and the sidewall of die receiving through hole) except the die 16 area for isolation. In one embodiment, the protective layer 26 is an elastic material, photosensitive material or dielectric material. Besides, a barrier layer 32 may be formed, such as by using a metal plating method, on side wall of the substrate 2 for better adhesion with the protective layer (isolating material). Another adhesive material 38 is formed over the die 16 to create an opening 46 and adhesive the transparent cover 36 to create an air gap between the transparent cover 36 and the micro lens area 42. The wire bonding 24 is formed on the die 16, wherein the wire bonding 24 keeps electrically connected with the die 16 through the I/O pads 20 and the contact pads 22, thereby forming inter-connecting contact to contact the terminal pads 8. The aforementioned structure constructs LGA type (terminal pads in the peripheral of package) package.

It should be noted that the opening 46 is formed on the die 16 and a protection layer 40 to expose the micro lens area 42 of the die 16 for CMOS Image Sensor (CIS). The protection layer 40 can be formed over the micro lens on the micro lens area 42. The image sensor chips have been coated the protection layer (film) 40 on the micro lens area; the protection layer (film) 40 with the properties of water repellent and oil repellent that can away the particle contamination on the micro lens area. The thickness of protection layer (film) 40 is preferably around 0.1 um to 0.3 um and the reflection index close to the air reflection index 1. The process can be executed by SOG (spin on glass) skill and it can be processed in silicon wafer form. The materials of protection layer can be SiO₂, Al₂O₃ or Fluoro-polymer etc.

Finally, a transparent cover 36 with coating IR filter (optionally) is formed over the micron lens area 42 for protection. The transparent cover 36 is composed of glass, quartz, etc.

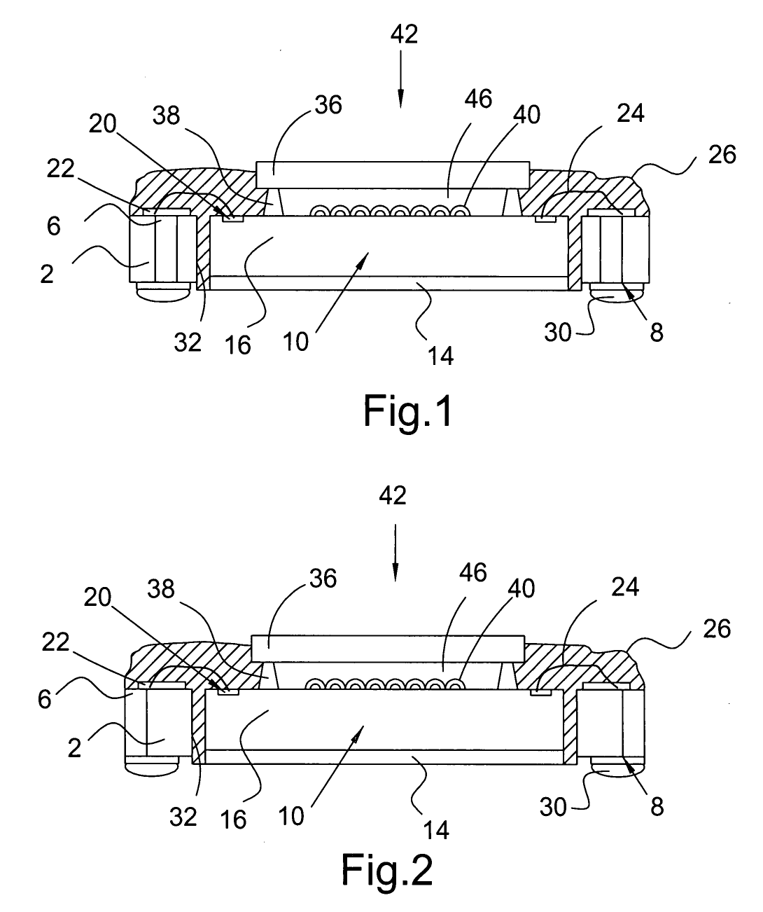

An alternative embodiment can be seen in FIG. 2, conductive balls 30 are formed under the contact terminal pads 8. This type is called BGA (Ball Grid Array) type. In FIG. 2, the contact (inter-connecting) through holes 6, for instance semi-spherical shape, is formed in a scribe line area passing through the substrate 2, the semi-spherical sharp for inter-connecting through holes 6 also can be formed in the sidewall area of the die receiving through hole (not shown), the other parts are similar to FIG. 1; therefore, the reference numbers of the similar parts are omitted. The contact through holes 6 is in the scribe line; therefore each package has half through hole such that improve the solder join quality and reduce the foot print. Preferably, the material of the substrate 2 is organic substrate likes FR5, FR4, BT (Bismaleimide triazine), PCB with defined opening or Alloy42 with pre etching circuit. The organic substrate with high Glass transition temperature (Tg) are epoxy type FR5 or BT (Bismaleimide triazine) type substrate for better process performance. The Alloy42 is composed of 42% Ni and 58% Fe. Kovar can be used also, and it is composed of 29% Ni, 17% Co, 54% Fe. The glass, ceramic, silicon can be used as the substrate due to lower CTE.

The substrate could be rectangular type such as panel form, and the dimension could be fit into the wire bonder machine. As shown in FIGS. 1 and 2, the wire bonding 24 fans out of the die and communicates with the contact pads 22 and I/O metal pads 20. It is different from the prior art technology which stacks layers over the die, thereby increasing the thickness of the package. However, it violates the rule to reduce the die package thickness. On the contrary, the terminal pads 8 are located on the surface that is opposite to the die pads side. The communication traces are penetrates through the substrate 2 via the contact through holes 6 and leads the signal to the terminal pads 8. Therefore, the thickness of the die package is apparently shrinkage. The package of the present invention will be thinner than the prior art. Further, the substrate is pre-prepared before package. The die through hole 10 and the contact through holes 6 are pre-determined as well. Thus, the throughput will be improved than ever. The present invention discloses a PLP without stacked built-up layers over the wire bonding.

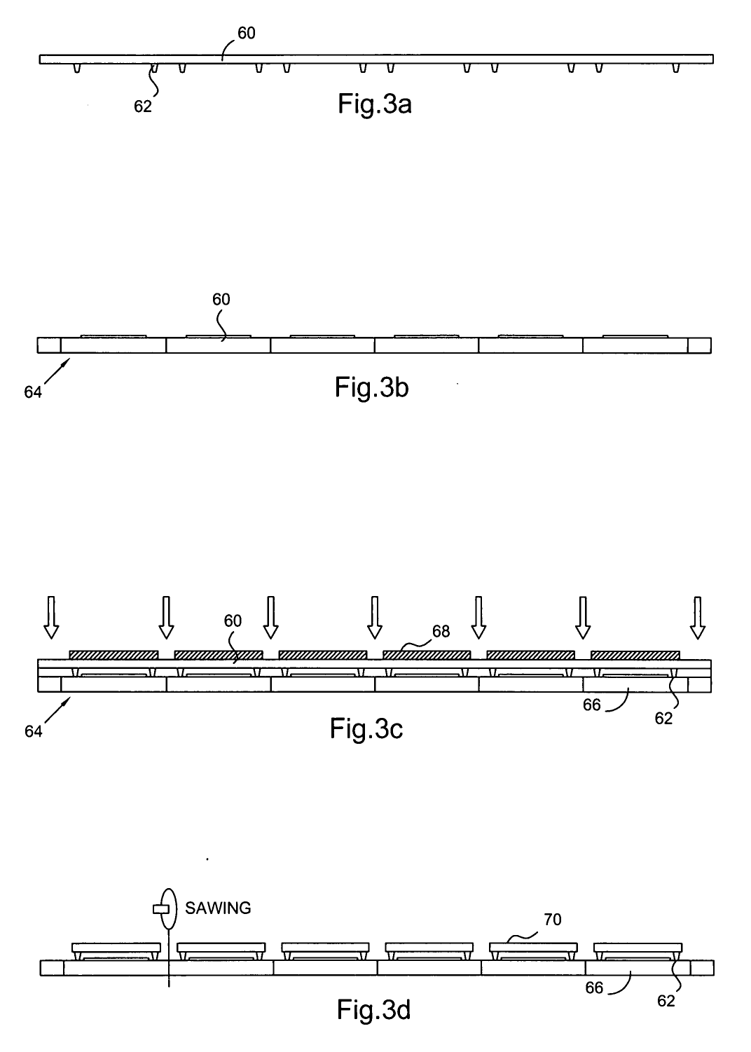

FIGS. 3a˜3d illustrate process steps for making CIS chips with protection transparent cover for the panel/wafer form (cross section). As can be seen from the FIG. 3a, the process for the above mentioned includes providing an adhesive material 62 formed pattern over a transparent panel, such as glass panel, or layer 60 by employing printing or dispenser, preferable UV type, to create a space for exposing micro lens area with a gap. A wafer 64 with chips (dice) 66 is provided, shown as FIG. 3b. And then, the transparent panel 60 is attached to the wafer 64 by panel bonding through the adhesive material 62. It should be noted that the adhesive material 62 surrounds the micro lens area to expose micro lens area, and thereby the transparent panel 60 protecting micro lens from contaminations. Subsequently, a photo resist pattern 68 is defined on the transparent panel 60 such that the photo resist pattern 68 aligns to the micro lens area, shown in FIG. 3c. The transparent panel 60 is then etched, such as dry etching or wet etching, to make plurality of transparent covers 70. Remaining photo resist pattern 68 is then removed. Finally, the wafer 64 is separated, for instance by sawing the wafer substrate at a scribe line, to be plurality of individual units (CIS chips) with protection transparent cover 70, shown in FIG. 3d. The scribe line is located at the etched area which is defined between the units for separating each of the units.

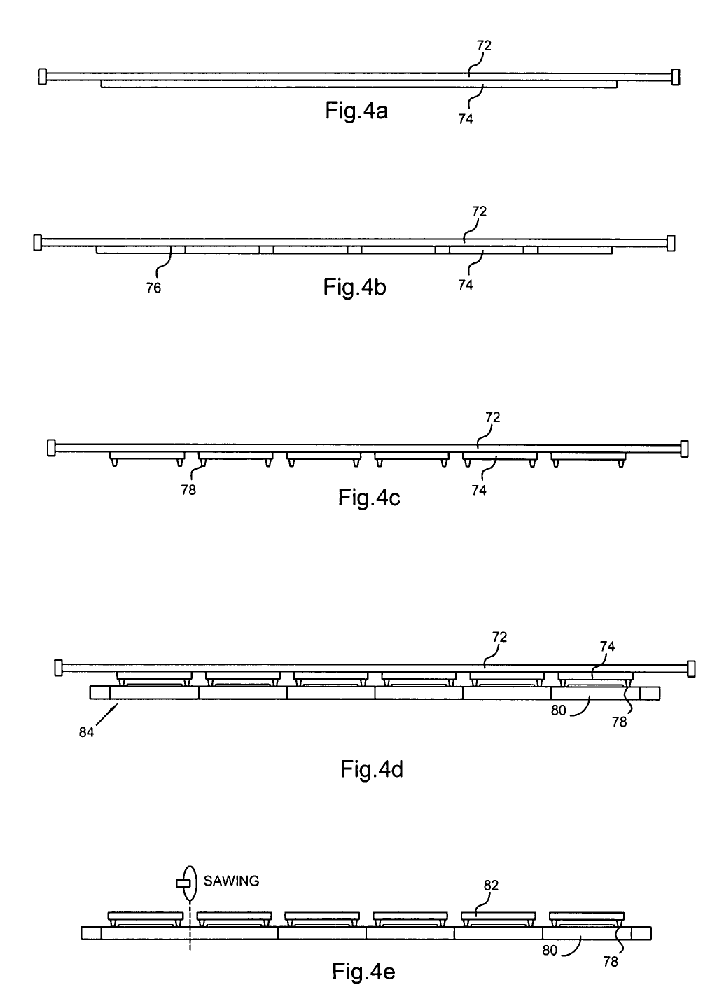

FIGS. 4a˜4e illustrate process steps for making CIS chips with protection transparent cover for the panel/wafer form (cross section) according to another embodiment of the present invention. As seen from the FIG. 4a, the process for the above mentioned includes providing a transparent panel or layer 74 attached to an adhesive tape 72, such as blue tape or UV tape. The transparent panel 74 is scribed and broken to be plurality of determined scribe lines 76, shown in FIG. 4b. An adhesive material 78 is then formed over the transparent panel 74 by employing printing or dispenser, preferable UV type, to create a space for exposing micro lens, shown as FIG. 4c. It is noted that the adhesion material 78 maybe printing or dispensing on the CIS wafer 84. And then, the transparent panel 74 is attached to a wafer 84 with chips (dice) 80 by panel bonding through the adhesive material 78. It should be noted that the adhesive material 78 surrounds the micro lens area to expose micro lens area, and thereby the transparent panel 74 protecting micro lens from contaminations, shown in FIG. 4d. The scribe lines 76 align to the adhesive material 78, then to remove the adhesion tape and rest panel (glass). Finally, the wafer 84 is separated, for instance by sawing the wafer substrate at about center of adjacent scribe lines points, to be plurality of individual units (CIS chips) with protection transparent cover 82, shown in FIG. 4e. The scribe line is about located over the adhesive material 78 which is defined between the units for separating each of the units.

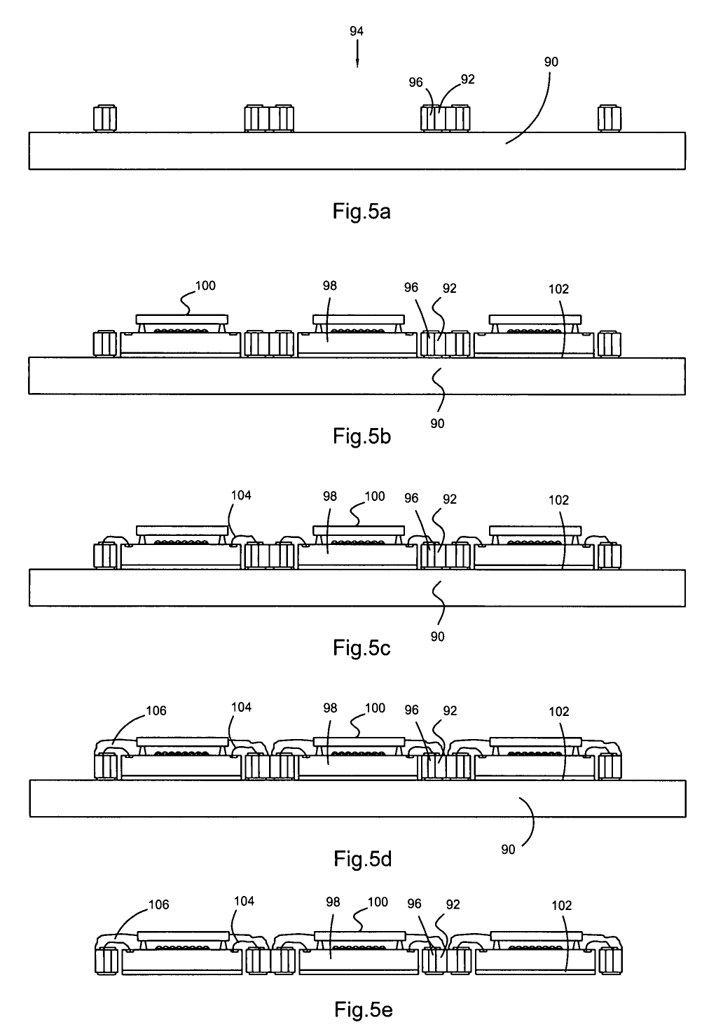

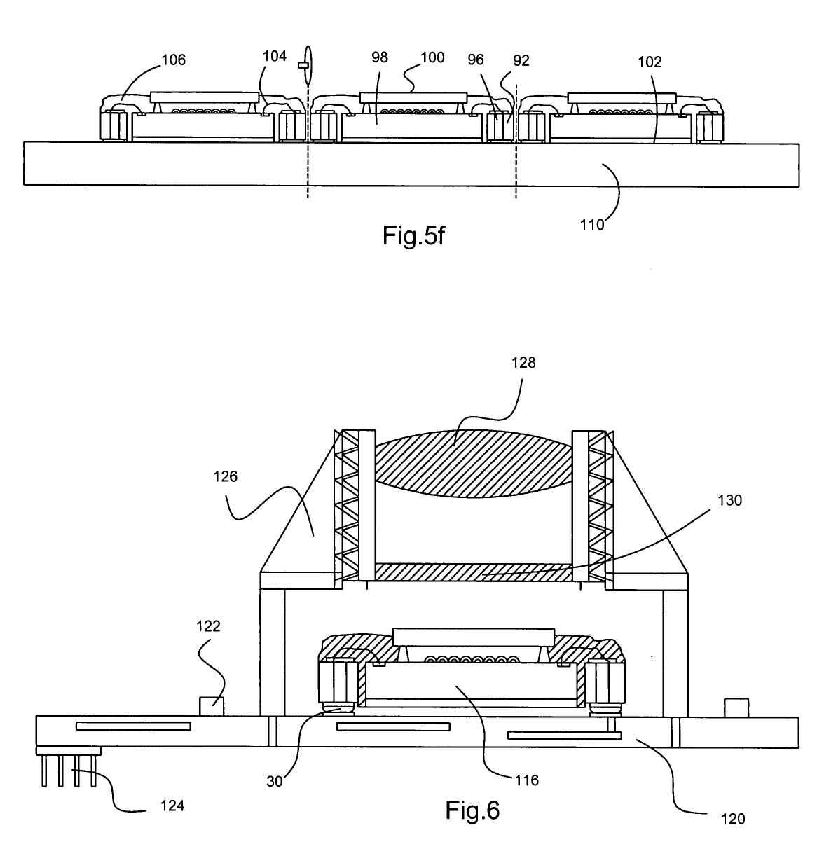

FIGS. 5a˜5f illustrate process steps for making panel level CIS chips scale package with protection transparent cover for the panel form (cross section). The process for the present invention includes providing an alignment tool (chips redistributed tool) 90 with alignment pattern formed thereon. Then, the pattern glues is printed on the tool 90 (be used for sticking the back side surface of dice), followed by using pick and place fine alignment system with die bonding function to re-distribute the known good dice on the tool with desired pitch. The pattern glues will stick the chips on the tool 90. Alternatively, a die attached tape can be used. Subsequently, a substrate 92 with die through holes 94 and contact through hole 96, and contact pad 22 on the upper side and terminal pads 8 on the lower side is provided on the tool 90, shown in FIG. 5a. A conductive material will be re-filled into the through holes 96 for electrical communication. Next, a die 98, for instant die of FIG. 1 and FIG. 2, with a protective glass (cover) 100 on the micro lens is inserted and attached into the die through holes 94 of the substrate 92 by the die attached tape 102 at die back side, shown in FIG. 5b. Then, a wire bonding 104 is formed to connect between pads of the die 98 and contact metal pads of the pre-formed substrate 92, shown in FIG. 5c. Subsequently, a protective layer 106, for instance liquid compound, is formed over to cover the wire bonding 104 for protection and fill into the gap between the die edge and the sidewall of the die through hole for adhesion the die and substrate, shown in FIG. 5d. The panel is separated from the tool after vacuum curing, shown in FIG. 5e.

After the ball placement or solder paste printing, the heat re-flow procedure is performed to re-flow on the substrate side (for BGA type). The testing is executed. Panel level final testing is performed by using vertical probe card. After the testing, the substrate 92 is sawed along the scribe line 108 to singulate and separate the package into individual units, shown in FIG. 5f. Then, the packages are respectively picked and placed the package (device) on the tray or tape and reel.

Referring to FIG. 6, it is an individual CMOS image sensor module by using CIS-CSP in this present invention. The die comprises CMOS sensor or CCD image sensor. Terminal conductive pads 30 of CIS-CSP 116 are connected (by SMT process—soldering join) to the connection pads of a flex printed circuit board 120 (FPC) with connector 124 (for connecting with mother board) formed thereon. CIS-CSP 116 is for example unit package of FIG. 1 and FIG. 2. Then, a lens 128 is disposed above the transparent cover (glass) 36 of CIS-CSP 116 to allow the light to pass through. As the same, a micro lens may be formed on the micro lens area, and an air gap is created between the die 16 and the transparent cover (glass) 36. A lens holder 126 is fixed on the printed circuit board 120 to hold the lens 128 on top of the CIS-CSP 116. A filter 130, such as IR filter, is fixed to the lens holder 126. Alternatively, the filter 130 may comprise a filtering layer, for example IR filtering layer, formed upper or lower surface of the transparent cover (glass) 36 to act as a filter. In one embodiment, IR filtering layer comprises TiO2, light catalyzer. The transparent cover (glass) 36 may prevent the micro lens from particles containment. The user may use liquid or air flush to remove the particles on the transparent cover (glass) 36 without damaging the micron lens. Moreover, a passive device 122 can be configured on the printed circuit board 120.

Hence, the advantages of the present invention are:

The substrate is pre-prepared with pre-form through hole and wiring circuit; it can generates the super thin package due to die insert inside the substrate, thickness under 200 um (from image sensor surface); it can be used as stress buffer releasing area by filling silicone rubber or liquid compound materials to absorb the thermal stress due to the CTE difference between silicon die (CTE˜2.3) and substrate (FR5/BT−CTE—16)). The packaging throughput will be increased (manufacturing cycle time was reduced) due to apply the simple process: die bonding, wire bonding, protection layer and sawing, it is due to the lower pin count structure of image sensor chips. The terminal pads are formed on the opposite surface to the dice active surface (pre-formed). The dice placement process is the same as the current process—die bonding. No particles contamination during process to module is produced for the present invention which is put the glass cover in wafer form once it is completed at fab. The surface level of die and substrate can be the same after die is attached on the die through hole of substrate. The package is cleanable due to glass cover on the micro lens. The chip scale package has size around chip size plus 0.5 mm/side. The reliability for both package and board level is better than ever, especially, for the board level temperature cycling test, it was due to the CTE of substrate and PCB mother board are identical, so, no thermal mechanical stress be applied on the solder bumps/balls. The cost is low and the process is simple. The manufacturing process can be applied fully automatic especially in module assembly by using the SMT process. It is easy to form the combo package (dual dice package). The LGA type package has peripheral terminal pads for SMT process. It has high yield rate due to particles free, simple process, fully automation.

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. A structure of image sensor package, comprising:
a substrate with a die through hole and contact through holes structure formed there through, wherein terminal pads are formed under said contact through hole structure and contact pads are formed on a upper surface of said substrate;
a die having a micro lens area disposed within said die through hole;
a wire bonding formed on said die and said substrate, wherein said wire bonding is coupled to said die and said contact pad;
a transparent cover disposed on said die within said die through hole by adhesion to create an air gap between said transparent cover; and
a protective layer covering over said wire bonding and filling into the gap between said die edge and the sidewall of said die through hole of said substrate.

2. The structure of claim 1, further comprising conductive bumps coupled to said terminal pads.

3. The structure of claim 1, wherein material said protective layer includes compound, liquid compound, silicone rubber.

4. The structure of claim 1, wherein said protective layer comprises elastic material, photosensitive material or dielectric material.

5. The structure of claim 1, further comprising a barrier layer formed on the sidewall of said die through hole of said substrate.

6. The structure of claim 5, wherein said barrier layer comprises a metal layer.

7. The structure of claim 1, wherein said contact through holes structure includes the semi-spherical sharp in the scribe line area or sidewall area of die through hole of said substrate.

8. The structure of claim 1, wherein the material of said substrate includes epoxy type FR5, FR4.

9. The structure of claim 1, wherein the material of said substrate includes BT.

10. The structure of claim 1, wherein the material of said substrate includes PCB (print circuit board).

11. The structure of claim 1, wherein the material of said substrate includes alloy or metal.

12. The structure of claim 1, wherein the material of said substrate includes glass, silicon, ceramic.

13. The structure of claim 1, further comprising a protection layer formed on said micro lens area to protect the micro lens away the particles contamination.

14. The structure of claim 13, wherein materials of said protection layer includes SiO₂, Al₂O₃ or Fluoro-polymer.

15. The structure of claim 13, wherein said protection layer with water repellent and oil repellent properties.

16. The structure of claim 1, wherein said transparent cover is coated IR filter formed over said micro lens area.

17. A method for forming semiconductor device package, comprising:
providing a substrate with die through holes and contact through holes structure formed there through on a tool, wherein terminal pads are formed under said contact through hole structure and contact pads are formed on a upper surface of said substrate;
attaching adhesive material on image sensor chips back side;
using a pick and place fine alignment system to re-distribute known good dice said image sensor chips on said tool with desired pitch;
forming a wire bonding to couple between said chip and contact pad of said substrate; and
forming a protective layer to cover said wire bonding, and fill into the gap between said die edge and the sidewall of said die through hole of said substrate, and vacuum curing then separating said tool.

18. The method of claim 17, wherein said image sensor chip has a protection layer formed on micro lens area to protect the micro lens away the particles contamination.

19. The method of claim 17, wherein said image sensor chip has a transparent cover adhesive on micro lens, and the adhesive material surrounds the micro lens area to expose said micro lens area.

20. The method of claim 17, further comprising a step of singulating said semiconductor device package into individual units.

21. A structure of image sensor module, comprising:
a flex print circuit board (FPC) with wiring circuit, connection pads and connector;
a solder paste to solder said connection pads of said FPC and the terminal pads of a substrate;
wherein said substrate has die through holes and contact through holes structure formed there through, wherein said terminal pads are formed under said contact through hole structure and contact pads are formed on a upper surface of said substrate;
a die having a micro lens area disposed within said die through hole;
a wire bonding formed on said die and said substrate, wherein said wire bonding is coupled to said die and said contact pad; and
a transparent cover disposed on said die within said die through hole by adhesion to create an air gap between said transparent cover and said micro lens area.
a protective layer covering over said wire bonding and filling into the gap between said die edge and the sidewall of said die through hole of said substrate; and
a lens holder with lens fixed on said FPC and disposed above said transparent cover to allow the light passing through said micro lens area.

22. The structure of claim 21, further comprising passive components soldering join on said FPC.
